(19) United States
(12) Patent Application Publication
(10) Pub. No.: US 2007/0102399 A1
(43) Pub. Date: May 10, 2007

(54) Method and apparatus for manufacturing a semiconductor device, control program and computer-readable storage medium

(75) Inventor: Kosuke Ogasawara, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/505,353

(22) Filed: Aug. 17, 2006

Related U.S. Application Data
(60) Provisional application No. 60/740,242, filed on Nov. 29, 2005.

(30) Foreign Application Priority Data
Nov. 7, 2005 (JP) 2005-321745

(51) Int. Cl. C23F 1/00; H01L 21/306; H01L 21/302; B44C 1/22

(52) U.S. Cl. 216/67; 438/710; 156/345.24

(57) ABSTRACT

A method for manufacturing a semiconductor device, includes a plasma etching process for performing a plasma etching on a substrate to be processed at least having a silicon nitride film, an antireflection film and a photo resist with an opening laminated on a silicon substrate in said order from the lower side, to thereby form in the silicon substrate a trench corresponding to the opening. The etchings of the antireflection film, the silicon nitride film and the silicon substrate are successively performed by using an etching gas at least containing an NF₃ gas, an SF₆ gas or a gaseous mixture of NF₃ and SF₆.

### FIELD OF THE INVENTION

The present invention relates to a semiconductor device manufacturing method including a plasma etching process for performing a plasma etching on a substrate to be processed which at least has a silicon nitride film, an antireflection film and a photo resist with openings formed on the substrate in this order from the lower side, to thereby form in the substrate trenches corresponding to the openings of the resist film for device isolation; and also relates to a semiconductor device manufacturing apparatus, a control program, and a computer-readable storage medium storing the control program to be used therefor.

### BACKGROUND OF THE INVENTION

In the field of manufacture of semiconductor devices, a shallow trench isolation (STI) structure is known for device isolation. In a manufacturing process for semiconductor device employing the STI structure, trenches are formed in a silicon substrate by plasma etching.

The plasma etching process for forming the trenches involves the steps of performing main etching for etching, for example, a silicon oxide film and a silicon nitride film formed on a silicon substrate by using a photo resist as a mask and CF₄ as an etching gas; performing overetching by using a gaseous mixture of NF₃ and NH₃ as an etching gas; and subsequently performing etching on the silicon substrate by using a gaseous mixture of HBr and oxygen (See Japanese Patent Laid-open Application No. 2000-299374).

Further, there is also known a technique for forming an antireflection film between the photo resist and the silicon nitride film. In case of using the antireflection film, a step of performing plasma etching on the antireflection film is performed prior to the plasma etching of the silicon nitride film and the like. For the plasma etching of the antireflection film, a gaseous mixture of CF₄, CH₂F₂ and O₂ is employed as an etching gas, for example.

As described, when forming trenches in the silicon substrate for device isolation of a STI structure, individual etching gases are used for the respective steps of etching the uppermost antireflection film by using the photo resist as a mask, etching the silicon nitride film and the like through the main etching process and the overetching process, and finally etching the silicon substrate. Thus, etching gases need to be changed for each processing step, which results in an increase of processing time and a reduction of throughput.

### SUMMARY OF THE INVENTION

It is, therefore, an object of the present invention to provide: a semiconductor device manufacturing method capable of reducing a processing time required to conduct a plasma etching for forming a trench for device isolation, while enhancing throughput and productivity; a semiconductor device manufacturing apparatus; a control program; and a computer-readable storage medium storing the control program.

In accordance with the present invention, there is provided a method for manufacturing a semiconductor device including a plasma etching process for performing a plasma etching on a substrate to be processed at least having a silicon nitride film, an antireflection film and a photo resist with an opening laminated on a silicon substrate in said order from the lower side, to thereby form in the silicon substrate a trench corresponding to the opening, wherein the etchings of the antireflection film, the silicon nitride film and the silicon substrate are successively performed by using an etching gas at least containing an NF₃ gas, an SF₆ gas or a gaseous mixture of NF₃ and SF₆.

Preferably, the etching gas further contains an additive gas, the additive gas being a CF₄ gas, a rare gas or a gaseous mixture of CF₄ and a rare gas.

Preferably, the additive gas further contains an oxygen gas.

Preferably, the ratio of a flow rate of the additive gas to a flow rate of the NF₃ gas, the SF₆ gas or the gaseous mixture of NF₃ and SF₆ (a flow rate of the additive gas/a flow rate of the NF₃ gas, the SF₆ gas or the gaseous mixture of NF₃ and SF₆) is set to be not smaller than 1.

Preferably, a silicon oxide film is formed between the silicon substrate and the silicon nitride film, and the silicon oxide film is also etched through the plasma etching process.

Preferably, the plasma etching process is performed in a processing chamber having therein a lower electrode for mounting thereon the substrate to be processed and an upper electrode facing the lower electrode by applying high frequency powers between the upper electrode and the lower electrode.

Preferably, the high frequency powers include a first high frequency power applied to the upper electrode and a second high frequency power applied to the lower electrode, and the second high frequency power is of a frequency lower than that of the first high frequency power.

Further, in accordance with the present invention, there is provided an apparatus for manufacturing a semiconductor device including: a processing chamber for accommodating a substrate to be processed; an etching gas supply unit for supplying an etching gas into the processing chamber; a plasma generating unit for converting the etching gas into plasma to thereby plasma-etch the substrate to be processed; and a control unit for controlling the methods described above.

Moreover, in accordance with the present invention, there is provided a control program, executed on a computer for controlling a semiconductor device manufacturing apparatus to perform the methods noted above.

In addition, in accordance with the present invention, there is provided a computer-readable storage medium for storing therein a computer-executable control program, wherein the control program controls, when executed, a plasma processing apparatus to perform the method described above.

In accordance with the preferred embodiment of the present invention, the whole processing time required for performing a plasma etching to form trenches for device isolation can be reduced comparing to the prior art, while enhancing throughput and productivity.

### BRIEF DESCRIPTION OF THE DRAWINGS

The above and other objects and features of the present invention will become apparent from the following description of preferred embodiments given in conjunction with the accompanying drawings, in which:

FIGS. 1A and 1B show cross sectional views of a semiconductor wafer to describe a semiconductor device manufacturing method in accordance with a first preferred embodiment of the present invention;

FIG. 2 illustrates a schematic configuration of a semiconductor device manufacturing apparatus in accordance with the present invention; and

FIGS. 3A and 3B present cross sectional views of a semiconductor wafer to describe a semiconductor device manufacturing method in accordance with a second preferred embodiment of the present invention.

### DETAILED DESCRIPTION OF THE PREFERRED EMBODIMENTS

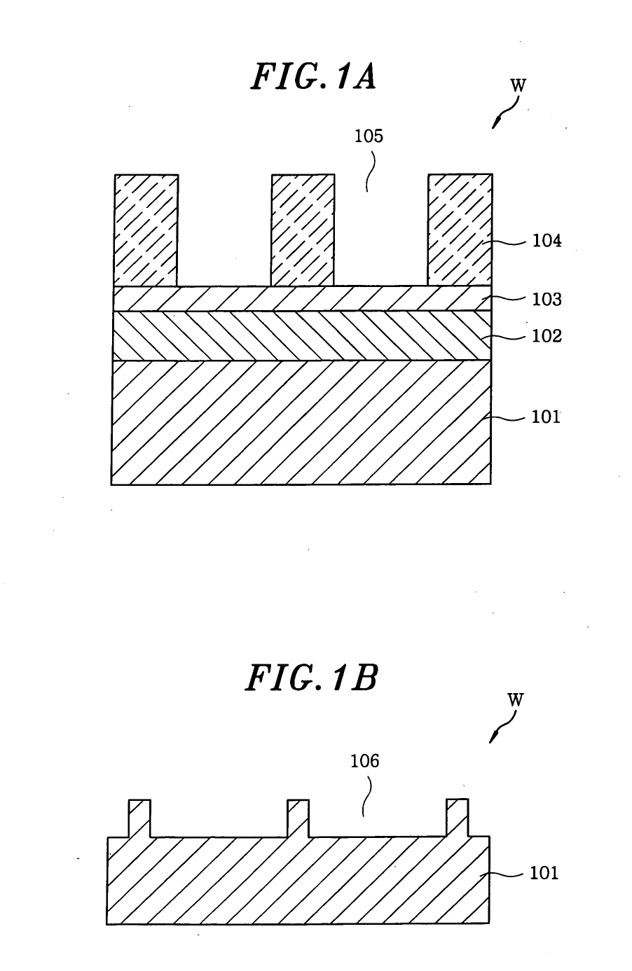

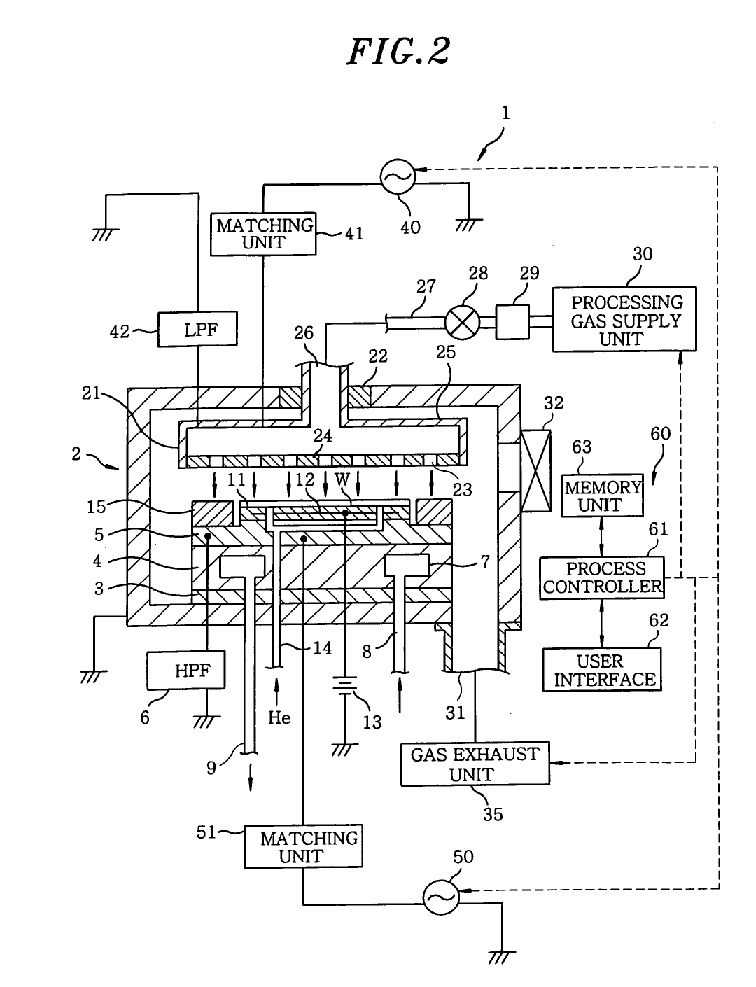

Hereinafter, preferred embodiments of the present invention will be described with reference to the accompanying drawings. FIGS. 1A and 1B are enlarged cross sectional views of a semiconductor wafer W to be processed according to a semiconductor device manufacturing method in accordance with a preferred embodiment of the present invention. Further, FIG. 2 sets forth a cross sectional view showing a schematic configuration of a plasma processing apparatus employed as a semiconductor device manufacturing apparatus in accordance with the preferred embodiment of the present invention. Below, the configuration of the plasma processing apparatus will be first explained in connection with FIG. 2.

A plasma processing apparatus 1 is configured as a capacitively coupled parallel plate type etching apparatus having an upper and a lower electrode plate placed to face each other in parallel and respectively connected to power supplies for plasma generation.

The plasma processing apparatus 1 has a cylindrical processing chamber (processing vessel) 2 formed of, for example, aluminum whose surface is anodically oxidized, and the chamber 2 is grounded.

Installed on a bottom portion of the processing chamber 2 via an insulating plate 3 such as ceramic is a substantially columnar susceptor support 4 for mounting, for example, a semiconductor wafer W thereon. Further, a susceptor 5 serving as a lower electrode is mounted on the susceptor support, and the susceptor 5 is connected to a high pass filter (HPF) 6.

A coolant chamber 7 is formed within the susceptor support 4, and a coolant is introduced into the coolant chamber 7 via a coolant introducing line 8. By the circulation of the coolant through the coolant chamber 7, heat transfer between the semiconductor wafer W and the coolant is carried out via the susceptor 5, whereby the semiconductor wafer W is maintained at a desired temperature level.

The susceptor 5 has an upper central portion of disk shape, which protrudes higher than its peripheral portion, and an electrostatic chuck 11 that is shaped substantially identical to the semiconductor wafer W is mounted on the upper central portion of the susceptor 5. The electrostatic chuck 11 includes an electrode 12 embedded in an insulating member. The electrostatic chuck 11 electrostatically adsorbs and holds the semiconductor wafer W by, for example, a Coulomb force generated by a DC voltage of, for example, 1.5 kV applied to the electrode 12 from a DC power supply 13 coupled to the electrode 12.

Further, formed through the insulating plate 3, the susceptor support 4, the susceptor 5 and the electrostatic chuck 11 is a gas channel 14 for supplying a heat transfer medium, for example, a helium (He) gas, to the rear surface of the semiconductor wafer W. Thus, heat is transferred between the susceptor 5 and the semiconductor wafer W through the heat transfer medium, so that the wafer W can be maintained at a predetermined temperature.

Moreover, an annular focus ring 15 is disposed on the upper peripheral portion of the susceptor 5 to surround the semiconductor wafer W loaded on the electrostatic chuck 11. The focus ring 15 is formed of a conductive material such as silicon and serves to improve uniformity of etching.

An upper electrode 21 is disposed above the susceptor 5 to face it in parallel and is supported at an upper portion of the processing chamber 2 via an insulating member 22. The upper electrode 21 includes an electrode plate 24 that faces the susceptor 5; and an electrode support 25 that serves to support the electrode 24 and is made of a conductive material. The electrode plate 24 is formed of, for example, aluminum whose surface is anodically oxidized (alumite treated) with a quartz cover attached thereto. Further, the electrode plate 24 is provided with a number of injection openings 23.

A gas inlet port 26 is formed at a center of the electrode support 25 of the upper electrode 21 and coupled to a gas supply line 27. Further, the gas supply line 27 is connected to a processing gas supply source 30 via a valve 28 and a mass flow controller 29.

A gas exhaust pipe 31 is connected to a bottom portion of the chamber 2 and coupled to a gas exhaust unit 35. The gas exhaust unit 35 includes a vacuum pump such as a turbo molecular pump, and serves to reduce the inner pressure of the chamber 2 down to a predetermined vacuum level, e.g., 1 Pa or less. Further, a gate valve 32 is installed on a sidewall of the chamber 2. The wafer W is transferred between the chamber 2 and an adjacent load lock chamber (not shown) while the gate valve 32 is opened.

A first high frequency power supply 40 is connected to the upper electrode 21 via a matching unit 41. Further, a low pass filter (LPF) 42 is coupled to the upper electrode 21. The first high frequency power supply 40 is of a frequency ranging from 50 to 150 MHz. By applying a high frequency power in such a range, a high-density plasma in a desirable dissociated state can be generated within the chamber 2.

Further, a second high frequency power supply 50 is connected to the susceptor 5 serving as the lower electrode via a matching unit 51. The second high frequency power supply 50 has a frequency range lower than that of the first high frequency power supply 40. By applying a power of a frequency in such a range, a proper ionic action can be facilitated without causing any damage on the wafer W. Preferably, the frequency of the second high frequency power supply 50 is determined within a range from about 1 to 20 MHz.

The whole operation of the plasma processing apparatus 1 having the above-described configuration is controlled by a control unit 60. The control unit 60 includes: a process controller 61 with a CPU for controlling each component of the plasma processing apparatus; a user interface 62; and a memory unit 63.

A process manager can operate the plasma processing apparatus 1 by using the user interface 62, wherein the user interface 62 includes a keyboard for inputting a command, a display for showing an operational status of the plasma processing apparatus, and the like.

Moreover, the memory unit 63 stores therein a control program (software) to be used in realizing various processings performed in the plasma processing apparatus under the control of the process controller 61, and/or recipes, each recipe containing processing condition data and the like. When a command is received from the user interface 62, the process controller 61 retrieves a necessary recipe from the memory unit 63 to execute it, so that a desired processing is performed in the plasma processing apparatus 1 under the control of the process controller 61. Further, the control program or the recipe containing processing condition data and the like can be retrieved from a computer-readable storage medium (such as a hard disk, a compact disk, a flexible disk, a semiconductor memory or the like) or retrieved on-line through, for example, a dedicated line from another apparatus available all the time.

Hereinafter, there will be described a sequence for plasma etching a semiconductor wafer W which at least has a silicon nitride film, an antireflection film and a photo resist with openings laminated on a silicon substrate in this order from the lower side, to thereby form in the silicon substrate trenches for device isolation, each trench corresponding to one of the openings of the resist, wherein the plasma etching is performed by the plasma processing apparatus 1 configured as described above. The gate valve 32 is opened first, and the semiconductor wafer W is loaded into the processing chamber 2 via a load lock chamber (not shown) to be finally mounted on the electrostatic chuck 11. Then, the semiconductor wafer W is adsorbed by the electrostatic chuck 11 to be held thereon by a DC voltage applied to the electrostatic chuck 11 from the DC power supply 13. Subsequently, the gate valve 32 is closed, and the processing chamber 2 is evacuated to a predetermined vacuum level by the gas exhaust unit 35.

Thereafter, the valve 28 is opened, and a predetermined etching gas is supplied into the hollow space of the upper electrode 21 via the gas supply line 27 and the gas inlet port 26 while its flow rate is controlled by the mass flow controller 29. Then, the etching gas is discharged uniformly toward the semiconductor wafer W through injection openings 23 of the electrode plate 24, as indicated by arrows in FIG. 2.

Then, while the internal pressure of the chamber 2 is maintained at a predetermined pressure level, a high frequency power of a predetermined frequency is applied to the upper electrode 21 from the first high frequency power supply 40, whereby a high frequency electric field is generated between the upper electrode 21 and the susceptor 5 serving as the lower electrode, so that the processing gas is dissociated and converted into plasma.

Meanwhile, another high frequency power of a frequency lower than that from the first high frequency power supply 40 is applied to the susceptor 5 serving as the lower electrode from the second high frequency power supply 50. As a result, ions among the plasma are attracted toward the susceptor 5, so that etching anisotropy is improved by ion assist.

Then, upon the completion of the plasma etching, the supply of the high frequency powers and the etching gas is stopped, and the semiconductor wafer W is retreated out of the processing chamber in the reverse sequence as described above.

Hereafter, a semiconductor device manufacturing method in accordance with the preferred embodiment of the present invention will be described. FIGS. 1A and 1B provide enlarged views to show a structure of major parts of a semiconductor wafer W to be processed. As shown in FIG. 1A, on the surface of a silicon substrate 101 forming the semiconductor wafer W, a silicon nitride film 102, an antireflection film (ARC) 103, and a photo resist 104 are laminated in this order from the lower side. The photo resist 104 is configured as a mask with openings of a predetermined pattern which is transferred thereto through an exposure and a developing process. The semiconductor wafer W is loaded into the processing chamber 2 of the plasma processing apparatus 1 in this state.

At an initial stage of an etching process in the processing chamber 2, the ARC film 103's and the silicon nitride film 102's portions located below openings 105 of the photo resist 104 are etched by using the photo resist 104 as a mask. After the photo resist 104 is completely etched, the ARC film 103 and the silicon nitride film 102 are etched entirely, during which the silicon substrate 101's portions once located below the openings 105, where the etching advances faster, are etched, so that trenches 106 for device isolation (STI) are formed in the silicon substrate 101, as shown in FIG. 1B. This plasma etching process is performed successively by using a single etching gas at least containing an NF₃ gas, an SF₆ gas, or a gaseous mixture of NF₃ and SF₆ without having to change etching gases for the etching of the ARC film 103, the silicon nitride film 102 and the silicon substrate 101 individually.

Preferably, the etching gas containing the NF₃ gas, the SF₆ gas, or the gaseous mixture of NF₃ and SF₆ further contains an additive gas, wherein the additive gas is one of, for example, a CF₄ gas, a rare gas or a gaseous mixture of CF₄ and a rare gas. Further, a gas further containing an oxygen gas in addition to the additive gas can also be appropriately utilized. Moreover, the ratio of a flow rate of the additive gas to a flow rate of the NF₃ gas, the SF₆ gas or the gaseous mixture of NF₃ and SF₆ (a flow rate of the additive gas/a flow rate of the NF₃ gas, the SF₆ gas or the gaseous mixture of NF₃ and SF₆), is preferably set to be not smaller than a value of 1. By controlling the flow rate of the additive gas, the etching rate of the silicon nitride film 102, which is used as a mask when etching the silicon substrate 101, can be controlled appropriately. That is, by increasing the flow rate of the additive gas, the etching rate of the silicon nitride film 102 can be reduced. Accordingly, by setting the ratio to be not smaller than 1, the etching rate of the portion serving as the mask can be reduced to obtain a trench of a desired depth. For example, a gaseous mixture of a CF₄ gas, an NF₃ gas, and an O₂ gas may be employed as the etching gas.

In a test experiment, a plasma etching as described above was performed on a semiconductor wafer having a structure as illustrated in FIG. 1A by using the plasma etching apparatus shown in FIG. 2 according to a recipe to be described below, to thereby obtain trenches 106.

Further, the processing recipe for the plasma etching is recorded in the memory unit 63 of the control unit 60 to be read and executed by the process controller 61. The processing controller 61 controls each component of the plasma processing apparatus 1 in compliance with a control program so that an etching process is executed according to the recipe.

The processing recipe is as follows:

etching gas: CF₄/NF₃/O₂=250/70/6 sccm;

pressure: 8.0 Pa (60 mTorr);

power (upper electrode/lower electrode): 550 W (60 MHZ)/500 W (13.56 MHZ); and

etching time: 1 minute.

After completing the plasma etching process, the semiconductor wafer W was observed through an electron microscope, and trenches 106 of desired shapes were found to be formed in a silicon substrate 101, as shown in FIG. 1B. Here, the widths of mask portions between the trenches 106 were found to be smaller than initial states (shown in FIG. 1A) by about 30 nm. Therefore, it is necessary to set the widths of openings 105 at an initial stage to be smaller than the desired widths of the trenches 106 by about 30 nm. In addition, conventionally, a plasma etching was conducted according to a recipe as follows, for example:

(Etching of an ARC Film)

etching gas: CF₄/CH₂F₂/O₂=160/20/30 sccm;
pressure: 4.7 Pa (35 mTorr);
power (upper electrode/lower electrode): 600 W (60 MHz)/75 W (13.56. MHZ);
etching time: about 1 minute
   (Etching of a Silicon Nitride Film)
   Main Etching
etching gas: CF₄/CHF₃/O₂=250/70/6 sccm;
pressure: 8.0 Pa (60 mTorr);
power (upper electrode/lower electrode): 550 W (60 MHZ)/500 W (13.56 MHZ);
   Overetching
etching gas: CHF₃/CH₃F/Ar/O₂=30/100/500/50 sccm
pressure: 6.7 Pa (50 mTorr)
power (upper electrode/lower electrode): 300 W (60 MHz)/150 W (13.56 MHz);
etching time (main etching+overetching): about 1.5 minutes
   (Etching of a Silicon Substrate)
etching gas: Cl₂/HBr/O₂=200/200/20 sccm;
pressure: 6.7 Pa (50 mTorr);
power (upper electrode/lower electrode): 500 W (60 MHz)/250 W (13.56 MHz); and
etching time: about 0.5 minute.

As can be seen from the above recipes, about 3 minutes of etching time was required in the conventional method of performing a plasma etching by changing etching gases for each of the ARC film 103, the silicon nitride film 102 and the silicon substrate 101, whereas just 1 minute was needed in the test experiment in accordance with the preferred embodiment of the present invention. That is, at least about 2 minutes can be reduced in accordance with the present invention. Further, in case of performing the plasma etching by changing etching gases for each of the layers, additional time is required for the changing work of the etching gases, so that the entire processing time would be further increased.

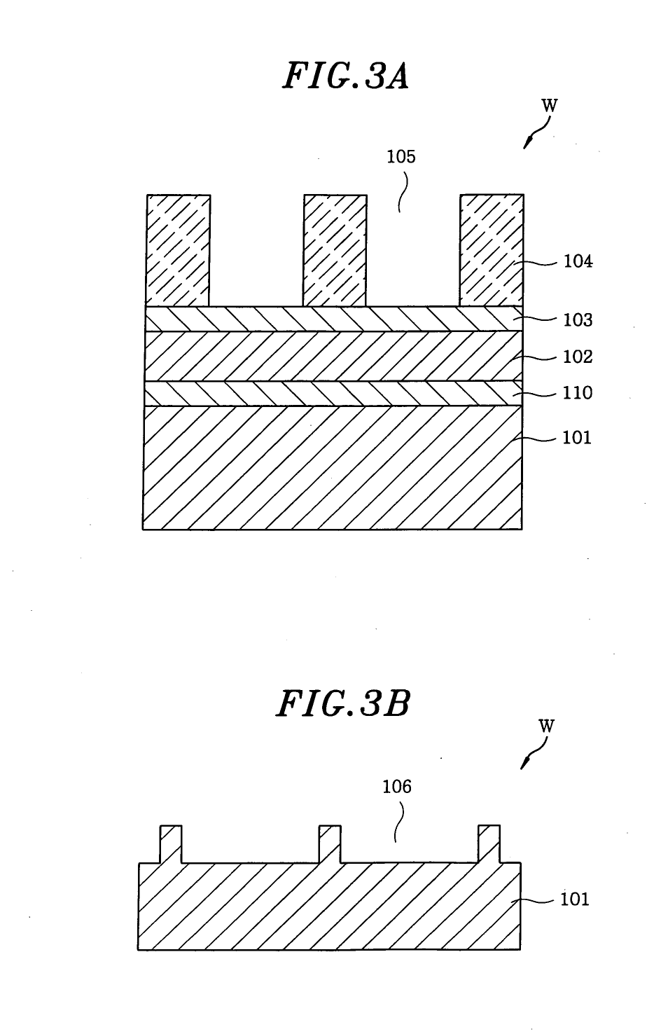

Also, though the preferred embodiment of the present invention has been described for the case of using a gas containing an NF₃ gas as an etching gas, a gas containing an SF₆ gas in which fluorine dissociates like the NF₃ gas or a gas containing an NF₃ gas and an SF₆ gas can be employed as the etching gas. Further, the substrate to be processed is not limited to a semiconductor wafer W having a structure as described in FIG. 1A. For example, the present invention can also be applied to the case of forming trenches 106 (see FIG. 3B) on a semiconductor wafer having a silicon oxide film 110 between a silicon substrate 101 and a silicon nitride film 102, as illustrated in FIG. 3A.

In accordance with the preferred embodiment of the present invention, the whole processing time required for performing a plasma etching to form trenches for device isolation can be reduced, while enhancing throughput and productivity. Furthermore, it is to be noted that the present invention is not limited to the preferred embodiment as described above but can be changed in various ways. For example, the plasma processing apparatus used in the present invention is not limited to the parallel plate type apparatus with an upper and a lower electrode to which high frequency powers are applied, as illustrated in FIG. 2, but various plasma processing apparatus such as a type of applying two high frequency powers to a lower electrode can be employed instead.

While the invention has been shown and described with respect to the preferred embodiments, it will be understood by those skilled in the art that various changes and modifications may be made without departing from the spirit and scope of the invention as defined in the following claims.

What is claimed is:

1. A method for manufacturing a semiconductor device, comprising a plasma etching process for performing a plasma etching on a substrate to be processed at least having a silicon nitride film, an antireflection film and a photo resist with an opening laminated on a silicon substrate in said order from the lower side, to thereby form in the silicon substrate a trench corresponding to the opening, wherein the etchings of the antireflection film, the silicon nitride film and the silicon substrate are successively performed by using an etching gas at least containing an NF₃ gas, an SF₆ gas or a gaseous mixture of NF₃ and SF₆.

2. The method of claim 1, wherein the etching gas further contains an additive gas, the additive gas being a CF₄ gas, a rare gas or a gaseous mixture of CF₄ and a rare gas.

3. The method of claim 2, wherein the additive gas further contains an oxygen gas.

4. The method of claim 2, wherein the ratio of a flow rate of the additive gas to a flow rate of the NF₃ gas, the SF₆ gas or the gaseous mixture of NF₃ and SF₆ (a flow rate of the additive gas/a flow rate of the NF₃ gas, the SF₆ gas or the gaseous mixture of NF₃ and SF₆) is set to be not smaller than 1.

5. The method of claim 3, wherein the ratio of a flow rate of the additive gas to a flow rate of the NF₃ gas, the SF₆ gas or the gaseous mixture of NF₃ and SF₆ (a flow rate of the additive gas/a flow rate of the NF₃ gas, the SF₆ gas or the gaseous mixture of NF₃ and SF₆) is set to be not smaller than 1.

6. The method of claim 1, wherein a silicon oxide film is formed between the silicon substrate and the silicon nitride film, and the silicon oxide film is also etched through the plasma etching process.

7. The method of claim 2, wherein a silicon oxide film is formed between the silicon substrate and the silicon nitride film, and the silicon oxide film is also etched through the plasma etching process.

8. The method of claim 3, wherein a silicon oxide film is formed between the silicon substrate and the silicon nitride film, and the silicon oxide film is also etched through the plasma etching process.

9. The method of claim 4, wherein a silicon oxide film is formed between the silicon substrate and the silicon nitride film, and the silicon oxide film is also etched through the plasma etching process.

10. The method of claim 5, wherein a silicon oxide film is formed between the silicon substrate and the silicon nitride film, and the silicon oxide film is also etched through the plasma etching process.

11. The method of claim 1, wherein the plasma etching process is performed in a processing chamber having therein a lower electrode for mounting thereon the substrate to be processed and an upper electrode facing the lower electrode by applying high frequency powers between the upper electrode and the lower electrode.

12. The method of claim 11, wherein the high frequency powers include a first high frequency power applied to the upper electrode and a second high frequency power applied to the lower electrode, and the second high frequency power is of a frequency lower than that of the first high frequency power.

13. An apparatus for manufacturing a semiconductor device, comprising:
a processing chamber for accommodating a substrate to be processed;
an etching gas supply unit for supplying an etching gas into the processing chamber;
a plasma generating unit for converting the etching gas into plasma to thereby plasma-etch the substrate to be processed; and
a control unit for controlling the method disclosed in claim 1.

14. A control program, executed on a computer for controlling a semiconductor device manufacturing apparatus to perform the method disclosed in claim 1.

15. A computer-readable storage medium for storing therein a computer-executable control program, wherein the control program controls, when executed, a plasma processing apparatus to perform the method disclosed in claim 1.
